(19) United States
(12) Patent Application Publication
(10) Pub. No.: US 2006/0043469 A1
(43) Pub. Date: Mar. 2, 2006

(54) SONOS memory cell and method of forming the same

(75) Inventors: Young-Sam Park, Suwon-si (KR); Seung-Beom Yoon, Suwon-si (KR); Seung-Jin Yang, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/124,716

(22) Filed: May 9, 2005

(30) Foreign Application Priority Data
Aug. 27, 2004 (KR) 2004-67909

(51) Int. Cl. H01L 29/792

(52) U.S. Cl. 257/324

(57) ABSTRACT

A silicon-oxide-nitride-oxide-silicon (SONOS) memory cell and a method of forming the same are disclosed. The SONOS memory cell includes a substrate in which a recessed region having at least one side wall is arranged and a trap storage pattern with which the recessed region is filled with a first insulating film is interposed. A control gate electrode is arranged on the top surface of the substrate and the top surface of the trap storage pattern with a second insulating film interposed. First and second source/drain regions are arranged in the substrate on both sides of the control gate electrode. The top surface of the trap storage pattern is flat and is at least as high as the top surface of the substrate.

### CROSS-REFERENCE TO RELATED APPLICATIONS

This U.S. non-provisional patent application claims priority under 35 U.S.C. §119 to Korean Patent Application 2004-67909, filed on Aug. 27, 2004, the disclosure of which is incorporated by reference herein.

### BACKGROUND OF THE INVENTION

1. Field of the Invention

The present invention relates to a semiconductor device and a method of forming the same, and more particularly, to a silicon-oxide-nitride-oxide-silicon (SONOS) memory cell and a method of forming the same.

2. Description of the Related Art

A SONOS memory element is a nonvolatile semiconductor device in which stored data is maintained even if power supply is removed. The SONOS memory element is referred to as a metal-oxide-nitride-oxide-silicon (MONOS) memory element, and uses a trap storage layer that has deep level traps as an element for storing data. Accordingly, the SONOS memory element stores electrical charges in the deep level traps.

A hot carrier implanting method is used for storing charges in the SONOS memory cell. U.S. Pat. No. 5,768,192 to Eitan et al. discloses a SONOS memory cell in which a hot carrier implanting method is used. This is illustrated in FIG. 1 as a sectional view of a conventional SONOS memory cell.

Referring to FIG. 1, a first silicon oxide film 2, a silicon nitride film 3, a second silicon oxide film 4, and a gate electrode 5 are sequentially laminated on a semiconductor substrate 1. First and second source/drain regions 6a and 6b are arranged on the semiconductor substrate 1 on both sides of the gate electrode 5.

The operation principle of the SONOS memory cell of the above structure will be described. A gate programming voltage is applied to the gate electrode 5 and a ground voltage is applied to the first source/drain region 6a. A source/drain programming voltage is applied to the second source/drain region 6b. Therefore, a hot carrier implantation phenomenon occurs around the second source/drain region 6b such that a charging region k is formed in the silicon nitride film 3. The charging region k is adjacent to the second source/drain region 6b.

Accordingly, hot electrons generated during the hot carrier implantation phenomenon may travel in random directions. Therefore, the amount of the electrons implanted into the charging region k is much smaller than the amount of generated hot electrons such that programming efficiency may deteriorate. U.S. Pat. No. 5,768,192 discloses a method of solving such a problem by increasing the gate programming voltage to induce the hot electrons to the charging region k. However, such a method of increasing the gate programming voltage may cause various problems. For example, there may be a limit to inducing the hot electrons by the gate programming voltage in a state where the high source/drain programming voltage accelerating the electrons is applied to generate the hot carrier. That is, the force applied to the hot electrons may be in the direction of the vector sum of the electric field generated by the gate electrode 5 and the electric field generated by the second source/drain region 6b. Therefore, there is a limit to improving the programming efficiency by increasing the gate programming voltage. Also, the power consumption of the SONOS memory element may significantly increase by increasing the gate programming voltage. Accordingly, it is difficult to improve the programming efficiency or/and to reduce the power consumption in the SONOS memory element.

### SUMMARY OF THE INVENTION

In order to solve the above-described problems, it is an aspect of the present invention to provide a silicon-oxide-nitride-oxide-silicon (SONOS) memory cell with improved programming efficiency and a method of forming the same.

It is another aspect of the present invention to provide a SONOS memory cell with reduced power consumption and a method of forming the same.

Accordingly, there is provided a silicon-oxide-nitride-oxide-silicon (SONOS) memory cell. The SONOS memory cell comprises an arrangement having a substrate in which a recessed region having at least one side wall and a trap storage pattern with which the recessed region is filled with a first insulating film interposes. A control gate electrode is arranged on the top surface of the substrate and interposing with a second insulating film on the top surface of the trap storage pattern. The first and second source/drain regions are arranged in the substrate on both sides of the control gate electrode. The top surface of the trap storage pattern is flat and is at least as high as the top surface of the substrate.

According to an embodiment, a trench having two side walls with the bottom surface lower than the top surface of the substrate is arranged in the substrate. In such a case, the control gate electrode passes one side wall of the trench from the top surface of the substrate such that a part of the trench is covered with the control gate electrode. The part of the trench under the control gate electrode is filled with the trap storage pattern. The part of the trench filled with the trap storage pattern corresponds to the recessed region. The first source/drain region is arranged under the top surface of the substrate adjacent to one side wall of the control gate electrode and the second source/drain region is arranged under the bottom surface of the trench adjacent to the other side wall of the control gate electrode. The first insulating film is extended to interpose between the second insulating film under the control gate electrode and the top surface of the substrate. Here, the top surface of the trap storage pattern is preferably as high as the top surface of the first insulating film positioned on the top surface of the substrate.

According to an embodiment, a trench having both side walls and a bottom surface lower than the top surface of the substrate is arranged in the substrate and the trench may be filled with the trap storage pattern. Here, the trench corresponds to the recessed region. In such a case, the trap storage pattern is separated from the first and second source/drain regions and both the top surface of the trap storage pattern and the top surface of the substrate positioned on both sides of the trench are covered with the control gate electrode.

As another aspect of this invention, there is provided a method of forming a SONOS memory cell. The method comprises the steps of forming a trap storage pattern with which a recessed region arranged in a substrate is filled with a first insulating film interposed therein and a control gate electrode arranged on the top surface of the substrate and on the top surface of the trap storage pattern with a second insulating film interposed therein. The first and second source/drain regions are formed on the substrate on both sides of the control gate electrode. The recessed region has at least one side wall. The top surface of the trap storage pattern is flat and is at least as high as the top surface of the substrate.

According to an embodiment, the step of forming the trap storage pattern and the control gate pattern comprises the following steps. A trench is formed in a substrate. A first insulating film is conformably formed on the substrate. A trap storage film with which the trench is filled is formed on the substrate. The trap storage film is planarized by a chemical mechanical polishing (CMP) process to form a preliminary trap storage pattern with which the trench is filled. The second insulating film and a gate conductive film are sequentially formed on the substrate. The gate conductive film, the second insulating film, and the preliminary trap storage pattern are patterned to form the control gate electrode that passes one side wall of the trench from the top surface of the substrate such that a part of the trench is covered with the control gate electrode and the burial insulating pattern with which the part of the trench under the control gate electrode is filled. The part of the trench filled with the trap storage pattern corresponds to the recessed region.

According to an embodiment, the step of forming the trap storage pattern and the control gate electrode comprises the following steps. A trench is formed in a substrate. The first insulating film is conformably formed on the substrate. A trap storage film with which the trench is filled is formed on the substrate. The trap storage film is planarized by a CMP process to form the trap storage pattern with which the trench is filled. The control gate electrode with which the top surface of the trap storage pattern and the top surface of the substrate on both sides of the trench are covered is formed with the second insulating film interposed. The trap storage pattern is formed to be separated from the first and second source/drain regions. Here, the trench corresponds to the recessed region.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention. In the drawings:

FIG. 1 is a sectional view illustrating a conventional silicon-oxide-nitride-oxide-silicon (SONOS) memory cell;

FIG. 2 is a sectional view illustrating a SONOS memory cell according to an embodiment of the present invention;

FIGS. 3 to 6 are sectional views illustrating a method of forming the SONOS memory cell according to an embodiment of the present invention;

FIG. 7 is a sectional view illustrating another method of forming gate electrodes in the method of forming the SONOS memory cell according to an embodiment of the present invention;

FIG. 8 is a sectional view illustrating a SONOS memory cell according to another embodiment of the present invention; and

FIGS. 9 to 11 are sectional views illustrating a method of forming the SONOS memory cell according to another embodiment of the present invention.

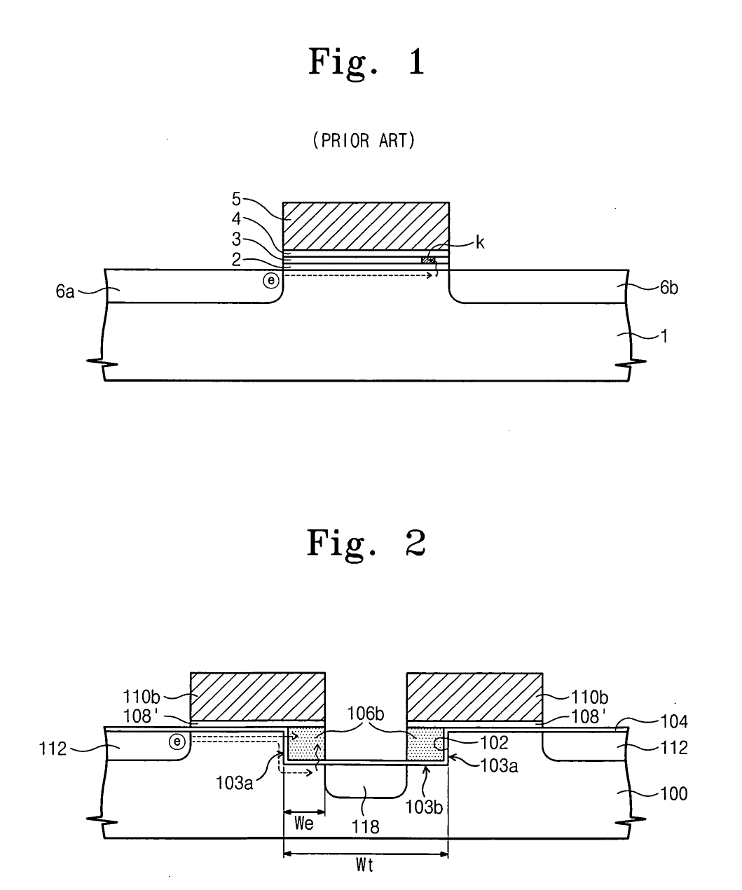

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the invention to those skilled in the art. In the drawings, the thickness of layers (or films) and regions are exaggerated for clarity. It will also be understood that when a layer (or a film) is referred to as being “on” another layer (or film) or substrate, it can be directly on the other layer or substrate, or intervening layers (or films) may also be present. The same reference numerals in different drawings represent the same element throughout the specification.

(First Embodiment)

FIG. 2 is a sectional view illustrating a silicon-oxide-nitride-oxide-silicon (SONOS) memory cell according to an embodiment of the present invention.

Referring to FIG. 2, a trench 102 is arranged in a predetermined region of a semiconductor substrate 100 (hereinafter, referred to as a substrate). The trench 102 has a bottom surface 103b that is lower than the top surface of the substrate 100 and both side walls 103a.

Control gate electrodes 110b are arranged on the substrate 100. Each of the control gate electrodes 110b extends from side to side on the top surface of the substrate 100 to pass one side wall of the trench 102 such that parts of the trench 102 are covered with the control gate electrodes 110b. The pair of control gate electrodes 110b are arranged to overlap the two edges of the trench 102, respectively.

The parts of the trench 102 covered with the control gate electrodes 110b are filled with trap storage patterns 106b. Here, the top surfaces of the trap storage patterns 106b are flat. Also, the top surfaces of the trap storage patterns 106b are at least as high as the top surface of the substrate 100. That is, the trap storage patterns 106b are as high as the top surface of the substrate 100 or higher than the top surface of the substrate 100. Due to the flat top surfaces of the trap storage patterns 106b and the height of the top surfaces of the trap storage patterns 106b, the bottom surfaces of the control gate electrodes 110b may be flat.

A first insulating film 104 is interposed between the trap storage patterns 106b and each one side wall 103a of the trench 102 and between the trap storage patterns 106b and the bottom surface 103b of the trench 102. The first insulating film 104 corresponds to a tunnel insulating film. Second insulating films 108′ are interposed between the top surface of the substrate 100 and the control gate electrodes 110b and between the top surfaces of the trap storage patterns 106b and the control gate electrodes 110b. The bottom surfaces of the control gate electrodes 110b directly contact the second insulating films 108′. The second insulating films 108′ correspond to blocking insulating films.

Parts of the trench 102 filled with the trap storage patterns 106b may be defined as recessed regions. The recessed regions are defined as spaces surrounded by each one side wall 103a of the trench 102 and parts of the bottom surface 103b of the trench 102. That is, each one side wall 103a of the trench 102 and parts of the bottom surface 103b correspond to the side walls 103a of the recessed regions and the bottom surfaces of the recessed regions. Here, one side of each of the recessed regions that faces the side wall 103a of each of the recessed regions is opened. The width “We” of each of the bottom surfaces of the recessed regions is smaller than the width “Wt” of bottom surface of the trench 102.

The top surfaces of the trap storage patterns 106b are flat and at least as high as the top surface of the substrate 100. Also, the recessed regions are filled with the trap storage patterns 106b. Therefore, the recessed regions are completely covered with the trap storage patterns 106b to the uppermost portions of the side walls 103a thereof.

The pair of recessed regions is arranged at the two edges of the trench 102. The pair of recessed regions is filled with the trap storage patterns 106b. The pair of trap storage patterns 106b is covered with the pair of control gate electrodes 110b, respectively. Therefore, a pair of SONOS memory cells is symmetrically arranged in the trench 102.

First and second source/drain regions 112 and 118 are arranged in the substrate 100 on both sides of the control gate electrodes 110b. Each of the first source/drain regions 112 is arranged under the top surface of the substrate 100 on one side of each of the control gate electrodes 110b. The second source/drain region 118 is arranged under the bottom surface 103b of the trench 102 on the other sides of the control gate electrodes 110b. That is, the top surface of the second source/drain region 118 is lower than the top surfaces of the first source/drain regions 112. The pair of SONOS memory cells illustrated in FIG. 2 shares the second source/drain region 118. One side wall of each of the trap storage patterns 106b adjacent to the second source/drain region 118 is preferably aligned with one side wall of each of the control gate electrodes 110b adjacent to the second source/drain region 118.

One end of the first insulating film 104 preferably extends to be interposed between the top surface of the substrate 100 and the second insulating films 108′ under the control gate electrodes 110b. Here, the top surfaces of the trap storage patterns 106b are preferably as high as the top surface of the first insulating film on the top surface of the substrate 100. Therefore, the recessed regions are completely covered with the trap storage patterns 106b to the uppermost portions of the side walls 103a thereof.

The second insulating films 108′ extend from side to side such that the first source/drain regions 112 are covered with the second insulating films 108′. At this time, one end of the first insulating film 104 may further extend such that the first source/drain regions 112 are covered with the first insulating film 104. In another embodiment, only the first insulating film 104 may be arranged on the first source/drain regions 112. The other end of the first insulating film 104 may extend such that the second source/drain region 118 is covered with the first insulating film 104.

The first insulating film 104 may be formed of a silicon oxide film, in particular, a thermal oxide film. The trap storage patterns 106b are formed from a material that has deep level traps. For example, the trap storage patterns 106b may be formed from a silicon nitride film. The second insulating films 108′ may be formed from the silicon oxide film, in particular, a chemical vapor deposition (CVD) silicon oxide film. In another embodiment, the second insulating films 108′ may contain a high dielectric material with a higher dielectric constant than that of the silicon nitride film. For example, the second insulating films 108′ may be formed of a metal oxide film such as an aluminum oxide film or a hafnium oxide film. The control gate electrodes 110b may contain doped polysilicon or a conductive metal containing material that is a conductive film. The conductive metal containing material may be at least one among metal (such as tungsten and molybdenum), a conductive metal nitride (such as titanium nitride and tantalum nitride), and metal silicide (such as tungsten silicide, cobalt silicide, titanium silicide, and nickel silicide). The source/drain regions 112 and 118 may be formed from an impurity doped layer.

A method of programming the SONOS memory cell of the above-described structure will now be described.

A ground voltage is applied to the first source/drain regions 112. A source/drain programming voltage is applied to the second source/drain region 118. A gate programming voltage is applied to the control gate electrodes 110b. Channels (inversion layers) are formed by the gate programming voltage under the control gate electrodes 110b. Electrons are flown by the source/drain programming voltage from the first source/drain regions 112 to the second source/drain region 118. The electrons are accelerated by the source/drain programming voltage to generate hot electrons. Here, the trap storage patterns 106b exist so as to vertically face the flow of the electrons. Therefore, the hot and/or accelerated electrons that travel in a horizontal direction may be directly implanted through the side walls 103a of the recessed regions. As a result, among the hot and/or accelerated electrons, not only the electrons implanted in the vertical direction but also the hot and/or accelerated electrons that travel in the horizontal direction are directly implanted in the trap storage patterns 106b such that the programming efficiency of the SONOS memory cell improves. Therefore, the gate and source/drain programming voltages may be reduced. In particular, even if the gate programming voltage is reduced to the degree where the channels are turned on, the SONOS memory cell may be sufficiently programmed. Therefore, it is possible to realize a SONOS memory element with low power consumption.

The channels are formed on the surface of the substrate 100 under the control gate electrodes 110b. Here, the top surfaces of the trap storage patterns 106b are as high as or higher than the top surface of the substrate 100 such that the recessed regions are completely covered with the trap storage patterns 106b to the uppermost portions of the side walls 103a thereof. Therefore, the hot and/or accelerated electrons that travel along the top surface of the substrate 100 on which the channels are formed in the horizontal direction are sufficiently implanted into the trap storage patterns 106b to improve the programming efficiency.

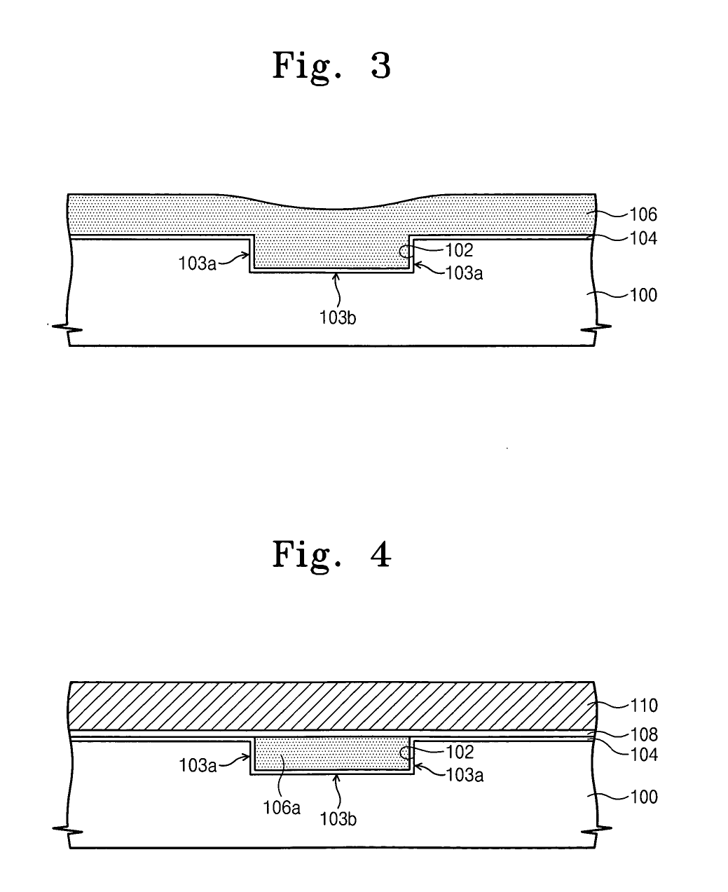

FIGS. 3 to 6 are sectional views illustrating a method of forming a SONOS memory cell according to an embodiment of the present invention.

Referring to FIG. 3, the trench 102 is formed in a predetermined region of the substrate 100. The trench 102 includes the bottom surface 103b that is lower than the two side walls 103a and the top surface of the substrate 100. The trench 102 may be formed using a hard mask. Before forming the trench 102, an element separating film (not shown) that defines an active region in the substrate may be formed. The trench 102 may be formed in the active region.

The first insulating film 104 is conformably formed on the entire surface of the substrate 100. The first insulating film 104 may be formed from a silicon oxide film. In particular, a thermal oxidation process may be performed on the substrate 100 that has the trench 102 to form the first insulating film 104.

A trap storage film 106 that fills the trench 102 is formed on the entire surface of the substrate 100 that has the first insulating film 104. The trap storage film 106 is formed of a material that has deep level traps. For example, the trap storage film 106 may be formed of a silicon nitride film.

Referring to FIG. 4, the trap storage film 106 is planarized until the first insulating film 104 positioned on the top surface of the substrate 100 is exposed to form a preliminary trap storage pattern 106a by filling in the trench 102. At this time, the top surface of the preliminary trap storage pattern 106a is formed to be as high as the top surface of the exposed first insulating film 104. Unlike the above description, the trap storage film 106 and the first insulating film 104 may be planarized until the top surface of the substrate 100 is exposed. In such a case, the top surface of the preliminary trap storage pattern 106a is formed to be as high as the top surface of the substrate 100.

The trap storage film 106 is preferably planarized by a chemical mechanical polishing (CMP) process. Therefore, it is possible to form the preliminary trap storage pattern 106a to be as high as the top surface of the exposed first insulating film 104 or the top surface of the substrate 100.

On the other hand, when the trap storage film 106 is planarized by an etch-back process, the top surface of the preliminary trap storage pattern 106a may be formed to be lower than the top surface of the substrate 100 due to over-etching. In such a case, the programming efficiency may deteriorate. On the other hand, when the trap storage film 106 is planarized by the above-described CMP process, the top surface of the preliminary trap storage pattern 106a may be formed to be as high as the top surface of the exposed first insulating film 104 or the top surface of the substrate. As a result, the trap storage film 106 is preferably planarized by the CMP process.

A second insulating film 108 and a gate conductive film 110 are sequentially formed on the entire surface of the substrate 100 that has the preliminary trap storage pattern 106a. The second insulating film 108 may be formed of a silicon oxide film, in particular, a CVD silicon oxide film. Unlike the above description, the second insulating film 108 may be formed of a high dielectric material with a higher dielectric constant than that of the silicon nitride film, for example, a metal oxide film such as an aluminum oxide film or a hafnium oxide film. The gate electrode 110 may contain doped polysilicon or a conductive metal containing material that is a conductive film. The conductive metal containing material may be the same material as described above.

Referring to FIG. 5, the gate conductive film 110 is patterned to form a gate conductive pattern 110a with which the preliminary trap storage pattern 106a and the top surface of the substrate 100 on both sides of the preliminary trap storage pattern 106a are covered.

Impurity ions are implanted using the gate conductive pattern 110a as a mask to form the first source/drain regions 112. The first source/drain regions 112 are formed under the top surface of the substrate 100 on both sides of the gate conductive pattern 110a.

A photosensitive film pattern 114 is formed on the substrate 100. The photosensitive film pattern 114 has an aperture 116 that exposes the central region of the gate conductive pattern 110a. The central region of the gate conductive pattern 110a that is exposed by the aperture 116 is arranged on the central region of the bottom surface 103b of the trench 102.

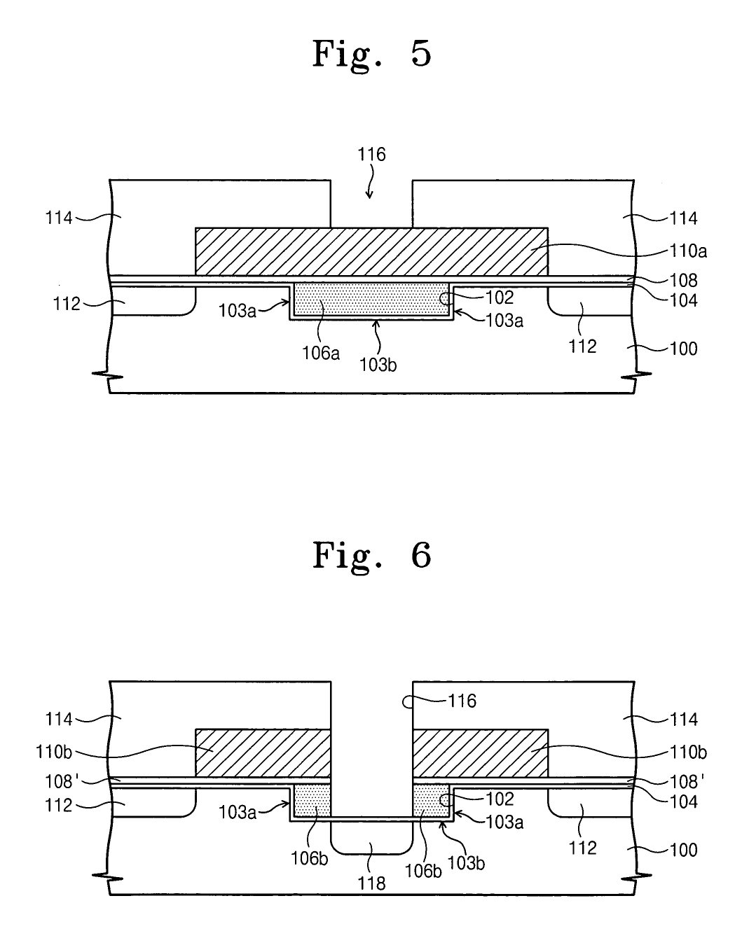

Referring to FIG. 6, the gate conductive pattern 110a, the second insulating film 108, and the preliminary trap storage pattern 106a are continuously etched using the photosensitive film pattern 114 as a mask. Therefore, trap storage patterns 106b, the patterned second insulating films 108′, and the control gate electrodes 110b that are sequentially laminated are formed. The control gate electrodes 110b are formed to pass side walls 103a of the trench 102 from the top surface of the substrate 100 such that the parts of the trench 102 are covered with the control gate electrodes 110b. The trap storage patterns 106b are formed such that parts of the trench 102 under the control gate electrodes 110b are filled with the trap storage patterns 106b. Due to the preliminary trap storage pattern 106a illustrated in FIG. 5, the top surfaces of the trap storage patterns 106b are flat and are as high as the top surface of the substrate 100 or the top surfaces of the second insulating films 104 on the top surface of the substrate 100. The parts of the trench 102 filled with the trap storage patterns 106b correspond to the above-described recessed regions. Therefore, the trap storage patterns 106b are formed such that the side walls 103a of the recessed regions are completely covered with the trap storage patterns 106b. The pair of trap storage patterns 106b that are symmetrical with each other and the pair of control gate electrodes 110b that are symmetrical with each other are formed by the above etching process.

Subsequently, impurity ions are implanted using the photosensitive film pattern 114 as a mask to form the second source/drain region 118 under the bottom surface 103b of the trench 102 between the pair of trap storage patterns 106b. Subsequently, the photosensitive film pattern 114 is removed to realize the SONOS memory cells illustrated in FIG. 2.

The first and second source/drain regions 112 and 118 are sequentially formed. Therefore, the impurity concentration or the junction depth of the first source/drain regions 112 may be different from the impurity concentration or the junction depth of the second source/drain region 118. Different voltages may be applied to the first and second source/drain regions 112 and 118. In particular, a higher voltage than the voltage applied to the first source/drain regions 112 may be applied to the second source/drain region 118. Therefore, it may be required that the impurity concentration or the junction depth of the first source/drain regions 112 be different from the impurity concentration or the junction depth of the second source/drain region 118. In such a case, the first and second source/drain regions 112 and 118 are sequentially formed to satisfy the above requirement.

As described above, the control gate electrodes 110b may be formed by performing a patterning process twice on the gate conductive film 110. Unlike the above description, the control gate electrodes 110b may be formed by performing the patterning process once on the gate conductive film 110, which will be described with reference to FIG. 7. The processes illustrated with reference to FIGS. 3 and 4 may also be used for this method.

FIG. 7 is a sectional view illustrating another method of forming gate electrodes in the method of forming the SONOS memory cell according to an embodiment of the present invention.

Referring to FIGS. 4 and 7, a pair of photosensitive film patterns 122 is formed on the gate conductive film 110. The gate conductive film 110, the second insulating film 108, and the preliminary trap storage pattern 106a are continuously etched using the photosensitive film pattern 122 as a mask to form the trap storage patterns 106b and the control gate electrodes 110b. That is, according to the present invention, a patterning process is performed once on the gate conductive film 110 to form the control gate electrodes 110b. At this time, patterned second insulating films 108″ reside only under the control gate electrodes 110b.

Impurity ions are implanted using the control gate electrodes 110b as masks to form the first and second source/drain regions 112 and 118. In such a case, the first and second source/drain regions 112 and 118 may be formed simultaneously. Unlike the above description, the first and second source/drain regions 112 and 118 may be sequentially formed using mask patterns (not shown). When the first and second source/drain regions 112 and 118 are formed simultaneously, the first and second source/drain regions 112 and 118 preferably have the junction depth and the impurity concentration to the degree where the first and second source/drain regions 112 and 118 can stand a high voltage.

According to the above-described method of forming the SONOS memory cell, the recessed regions that have the side walls 103a are formed under the control gate electrodes 110b and are filled with the trap storage patterns 106b. Therefore, during a programming operation, the hot and/or accelerated electrons that travel in a horizontal direction are additionally implanted into the trap storage patterns 106b to improve the programming efficiency. Therefore, it is possible to reduce power consumption.

Also, the trap storage film 106 is planarized by the CMP process such that the top surfaces of the trap storage patterns 106b are flat and are at least as high as the top surface of the substrate 100. Therefore, the entire side walls 103a of the recessed regions are completely covered with the trap storage patterns 106b. Therefore, during the programming operation, it is possible to improve efficiency of implanting the hot and/or accelerated electrons that travel along the surface of the substrate 100 in which channels are formed in the horizontal direction.

(Second Embodiment)

According to the present embodiment, a recessed region different from the recessed regions illustrated in the above-described first embodiment is disclosed.

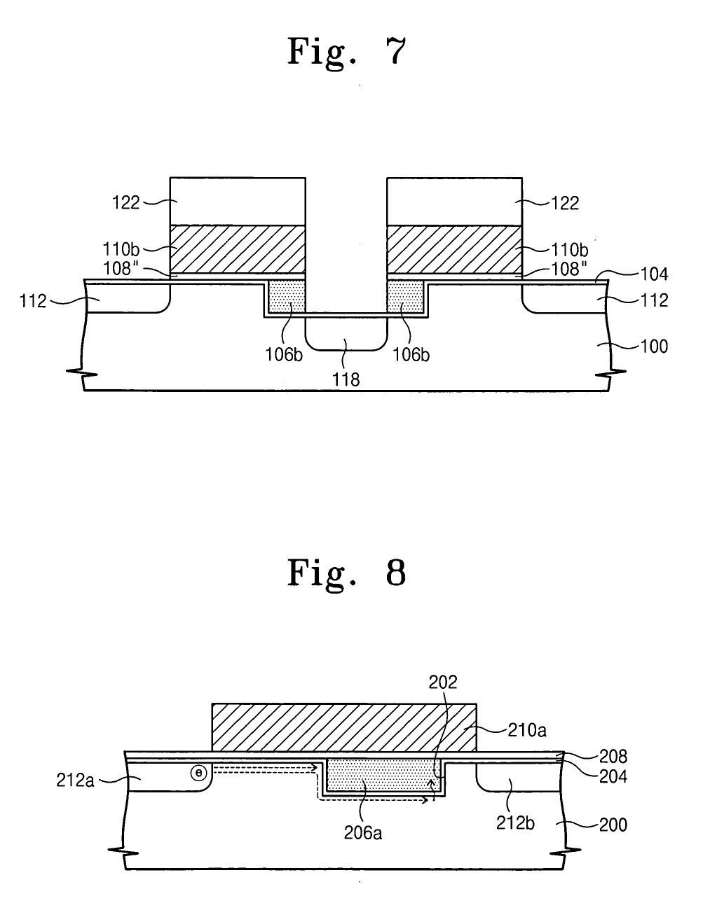

FIG. 8 is a sectional view illustrating a SONOS memory cell according to another embodiment of the present invention.

Referring to FIG. 8, a control gate electrode 210a is arranged on a substrate 200 and a trench 202 is arranged in the substrate 200 under the gate electrode 210a. The trench 202 has a bottom surface 203b lower than two side walls 203a and the top surface of the substrate 200. The trench 202 is filled with a trap storage pattern 206a with a first insulating film 204 interposed. At this time, the top surface of the tarp storage pattern 206a is flat and is at least as high as the top surface of the substrate 200. That is, the top surface of the trap storage pattern 206a is as high as the top surface of the substrate 200 or higher than the top surface of the substrate 200.

First and second source/drain regions 212a and 212b are arranged in the substrate 200 on both sides of the control gate electrode 210a. The first and second source/drain regions 212a and 212b are arranged under the top surface of the substrate 200. That is, the top surface of the first source/drain region 212a is as high as the top surface of the second source/drain region 212b.

The two side walls 203a of the trench 202 are separated from the first and second source/drain regions 212a and 212b. Therefore, the trap storage pattern 206a is separated from the first and second source/drain regions 212a and 212b. In other words, the trap storage pattern 206a and the top surface of the substrate 200 on both sides of the trap storage pattern 206a are covered with the control gate electrode 210a. A second insulating film 208 is interposed between the control gate electrode 210a and the top surface of the substrate 200 and the control gate electrode 210a and the trap storage pattern 206a.

Both ends of the first insulating film 204 may extend to be interposed between the second insulating film 208 under the control gate electrode 210a and the top surface of the substrate 200. In such a case, the trap storage pattern 206a is preferably as high as the top surface of the first insulating film 204 arranged on the top surface of the substrate 200.

The trench 202 corresponds to the recessed region under the control gate electrode 210a. That is, the recessed region according to the present embodiment is in the form of the trench that has the two walls 203a and the bottom surface 203b. The width of the trench 202 is preferably smaller than the width Wt of the trench 102 illustrated in FIG. 2 according to the first embodiment.

Hereinafter, the recessed region is denoted by the same reference numeral as the trench 202.

The recessed region 202 is filled with the trap storage pattern 206a and the top surface of the trap storage pattern 206a is flat and is as high as the top surface of the substrate 200 or the first insulating film 204 positioned on the top surface of the substrate 200. Therefore, the two walls 203a of the recessed region 202 are completely covered with the trap storage patterns 106b.

The programming operation of the above-described SONOS memory cell may be the same as illustrated in the above-described first embodiment. That is, a ground voltage is applied to the first source/drain region 212a, a source/drain program voltage is applied to the source/drain region 212b, and a gate program voltage is applied to the control gate electrode 210a. Therefore, the electrons of the first source/drain region 212a flow to the second source/drain region 212b along channels. At this time, the hot and/or accelerated electrons that travel in a horizontal direction by a horizontal electric field may be directly implanted into the trap storage pattern 206a through the side walls 203a of the recessed region 202. Also, the hot electrons that travel through the bottom surface 203b of the recessed region 202 in a vertical direction may be implanted into the trap storage pattern 206a. Therefore, the programming efficiency of the SONOS memory cell improves such that it is possible to reduce power consumption.

Also, since the recessed region 202 are completely covered with the trap storage pattern 206a to the uppermost portions of the side walls 203a thereof, the hot and/or accelerated electrons that travel along the surface of the substrate 200 in which the channels are formed in the horizontal direction may be sufficiently implanted into the trap storage pattern 206a. As a result, the programming efficiency of the SONOS memory cell further improves such that it is possible to realize a SONOS memory cell with low power consumption.

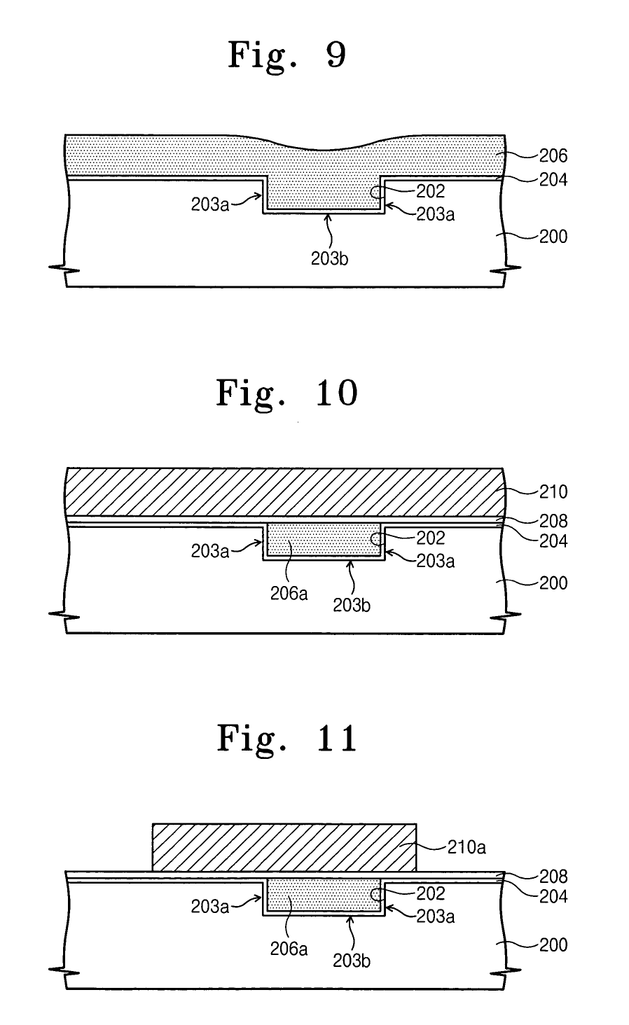

FIGS. 9 to 11 are sectional views illustrating a method of forming a SONOS memory cell according to an embodiment of the present invention.

Referring to FIG. 9, the trench 202 is formed in a predetermined region of the substrate 200. The trench 202 has the bottom surface 203b lower than the two side walls 203a and the top surface of the substrate 200. As described above, the trench 202 is defined as the recessed region.

The first insulating film 204 is conformably formed on the entire surface of the substrate 200. The first insulating film 204 may be formed of a silicon oxide film, in particular, a thermal oxide film. The first insulating film 204 is conformably formed along the top surface of the substrate 200 and the two side walls 203a and the bottom surface 203b of the trench 202.

A trap storage film 206 with which the trench 202 is filled is formed on the first insulating film 204. The trap storage film 206 may be formed of a material that has deep level traps such as a silicon nitride film.

Referring to FIG. 10, the trap storage film 206 is planarized to form the trap storage pattern 206a with which the trench 202 is filled. At this time, the trap storage film 206 is preferably planarized by the CMP process. Therefore, the top surface of the trap storage pattern 206a that is formed is flat. The trap storage film 206 is preferably planarized by the CMP process until the first insulating film 204 formed on the top surface of the substrate 200 is exposed. Therefore, the top surface of the trap storage pattern 206a may be formed to be as high as the exposed first insulating film 204. Unlike the above description, the trap storage film 206 and the first insulating film 204 may be planarized by the CMP process until the top surface of the substrate 200 is exposed. In such a case, the top surface of the trap storage pattern 206a may be formed to be as high as the top surface of the substrate 200.

The second insulating film 208 and a gate conductive film 210 are sequentially formed on the entire surface of the substrate 200. The second insulating film 208 may be formed of a silicon oxide film, in particular, a CVD silicon oxide film. Unlike the above description, the second insulating film 208 may be formed of a high dielectric material with a higher dielectric constant than that of the silicon nitride film, for example, a metal oxide film such as an aluminum oxide film or a hafnium oxide film. The gate electrode 210 may contain doped polysilicon or a conductive metal containing material that is a conductive film. The conductive metal containing material may be the same material as described above in the first embodiment.

Referring to FIG. 11, the gate conductive film 210 is patterned to form a control gate electrode 210a with which the trap storage pattern 206a and the top surface of the substrate 200 on both sides of the trap storage pattern 206a are covered.

Subsequently, impurity ions are implanted into the substrate 200 on both sides of the control gate electrode 210a to form the first and second source/drain regions 212a and 212b illustrated in FIG. 8. The first and second source/drain regions 212a and 212b may be simultaneously formed. Unlike the above description, since different voltages may be applied to the first and second source/drain regions 212a and 212b, it may be required that the impurity concentration and/or the junction depth of the first source/drain region 212a be different from the impurity concentration or/and the junction depth of the second source/drain region 212b. Therefore, the first and second source/drain regions 212a and 212b may be sequentially formed using mask patterns (not shown).

According to the above-described method of forming the SONOS memory cell, the trench 202 that is the recessed region is formed under the control gate electrode 210a and the trap storage film 206 is planarized by the CMP process to form the trap storage pattern 206a with which the trench 202 is filled. Therefore, since the hot and/or accelerated electrons that travel in the vertical and horizontal directions may be implanted into the trap storage pattern 206a during the programming operation, it is possible to improve the programming efficiency. As a result, it is possible to realize a SONOS memory element with low power consumption.

Also, since the two side walls 203a of the trench 202 are completely covered with the trap storage pattern 206a, it is possible to improve efficiency of implanting the electrons that travel along the channels formed on the surface of the substrate in the horizontal direction.

As described above, according to the present invention, the recessed region is arranged in the substrate under the gate electrode such that the recessed region is filled with the trap storage pattern. At this time, the top surface of the trap storage pattern is flat and is at least as high as the top surface of the substrate such that the side walls of the recessed region are completely covered with the trap storage pattern. Therefore, not only the hot electrons that travel in the vertical direction but also the hot and/or accelerated electrons that travel in the horizontal direction are directly implanted into the trap storage pattern. As a result, the programming efficiency of a SONOS memory cell improves such that it is possible to realize a SONOS memory element with low power consumption.

Also, since the recessed regions are completely covered with the trap storage pattern to the uppermost portions of the side walls thereof, it is possible to improve the efficiency of implanting the hot and/or accelerated electrons that travel along the surface of the substrate on which the channels are formed in the horizontal direction.

What is claimed is:

1. A silicon-oxide-nitride-oxide-silicon memory cell comprising:
a substrate in which a recessed region therein has at least one side wall;
a trap storage pattern with which the recessed region is filled with a first insulating film interposed therebetween;
a control gate electrode arranged on the top surface of the substrate and the top surface of the trap storage pattern with a second insulating film interposed therebetween; and
first and second source/drain regions formed in the substrate on both sides of the control gate electrode,
wherein the top surface of the trap storage pattern is flat and is at least as high as the top surface of the substrate.

2. The silicon-oxide-nitride-oxide-silicon memory cell as set forth in claim 1,
wherein a trench having a bottom surface lower than the side walls and the top surface of the substrate is arranged in the substrate;
wherein the control gate electrode passes one side wall of the trench from the top surface of the substrate such that the trench is partially covered with the control gate electrode;
wherein a portion of the trench under the control gate electrode is filled with the trap storage pattern; and
wherein the portion of the trench filled with the trap storage pattern is the recessed region.

3. The silicon-oxide-nitride-oxide-silicon memory cell as set forth in claim 2,
wherein the first source/drain region is arranged under the top surface of the substrate adjacent to one side wall of the control gate electrode; and
wherein the second source/drain region is arranged under the bottom surface of the trench adjacent to the other side wall of the control gate electrode.

4. The silicon-oxide-nitride-oxide-silicon memory cell as set forth in claim 3, wherein one side wall of the trap storage pattern adjacent to the second source/drain region and one side wall of the control gate electrode are aligned with each other.

5. The silicon-oxide-nitride-oxide-silicon memory cell as set forth in claim 2,
wherein a portion of the first insulating film extends to be interposed between the second insulating film under the control gate electrode and the top surface of the substrate; and
wherein the top surface of the trap storage pattern is as high as the top surface of the first insulating film positioned on the top surface of the substrate.

6. The silicon-oxide-nitride-oxide-silicon memory cell as set forth in claim 1,
wherein a trench having both side walls and a bottom surface lower than the top surface of the substrate is arranged in the recessed region on the substrate;
wherein the trench is at least partially filled with the trap storage pattern;
wherein the trap storage pattern is separated from the first and second source/drain regions; and
wherein the top surface of the trap storage pattern and the top surface of the substrate positioned on both sides of the trench are covered with the control gate electrode.

7. The silicon-oxide-nitride-oxide-silicon memory cell as set forth in claim 6,
wherein a portion of the first insulating film extends to be interposed between the second insulating film under the control gate electrode and the top surface of the substrate; and
wherein the top surface of the trap storage pattern is as high as the top surface of the first insulating film positioned on the top surface of the substrate.

8. A method of forming a silicon-oxide-nitride-oxide-silicon memory cell, comprising the steps of:
forming a trap storage pattern with which a recessed region arranged in a substrate is filled with a first insulating film interposed therebetween and a control gate electrode arranged on the top surface of the substrate and on the top surface of the trap storage pattern with a second insulating film interposed therebetween; and
forming first and second source/drain regions on the substrate on both sides of the control gate electrode,
wherein the recessed region has at least one side wall, and
wherein the top surface of the trap storage pattern is flat and is at least as high as the top surface of the substrate.

9. The method of forming a silicon-oxide-nitride-oxide-silicon memory cell as set forth in claim 8, wherein the step of forming the trap storage pattern and the control gate pattern comprises the steps of:
forming a trench in a substrate;
conformably forming a first insulating film on the substrate;
forming a trap storage film with which the trench is filled on the substrate;
planarizing the trap storage film by a chemical mechanical polishing process to form a preliminary trap storage pattern with which the trench is filled;
sequentially forming the second insulating film and a gate conductive film on the substrate; and
patterning the gate conductive film, the second insulating film, and the preliminary trap storage pattern to form the control gate electrode that passes one side wall of the trench from the top surface of the substrate such that a part of the trench is covered with the control gate electrode and the trap storage pattern with which the part of the trench under the control gate electrode is filled,
wherein the part of the trench filled with the trap storage pattern is the recessed region.

10. The method of forming a silicon-oxide-nitride-oxide-silicon memory cell as set forth in claim 9, which further comprises
arranging the first source/drain region under the top surface of the substrate adjacent to one side wall of the control gate electrode; and
arranging the second source/drain region under the bottom surface of the trench adjacent to the other side wall of the control gate electrode.

11. The method of forming a silicon-oxide-nitride-oxide-silicon memory cell as set forth in claim 10, which comprises forming the first and second source/drain regions sequentially.

12. The method of forming a silicon-oxide-nitride-oxide-silicon memory cell as set forth in claim 9, wherein the step of forming the control gate electrode, the trap storage pattern, and the first and second source/drain regions comprises the steps of:
patterning the gate conductive film to form a gate conductive pattern that extends from side to side from the top surface of the substrate such that the preliminary trap storage pattern is covered with the gate conductive pattern;
forming the first source/drain region under the top surface of the substrate on one side of the gate conductive pattern;
continuously patterning the gate conductive pattern, the second insulating film, and the preliminary trap storage pattern to form the trap storage pattern and the control gate electrode; and
forming the second source/drain region under the bottom surface of the trench on one side of the control gate electrode.

13. The method of forming a silicon-oxide-nitride-oxide-silicon memory cell as set forth in claim 12, which comprises
planarizing the trap storage film until the first insulating film positioned on the top surface of the substrate is exposed; and
arranging the preliminary trap storage pattern as high as the top surface of the exposed first insulating film.

14. The method of forming a silicon-oxide-nitride-oxide-silicon memory cell as set forth in claim 8, wherein the step of forming the trap storage pattern and the control gate electrode comprises the steps of:
forming a trench in a substrate;
conformably forming the first insulating film on the substrate;
forming a trap storage film with which the trench is filled on the substrate;
planarizing the trap storage film by a chemical mechanical polishing process to form the trap storage pattern with which the trench is filled; and
forming the control gate electrode with which the top surface of the trap storage pattern and the top surface of the substrate on both sides of the trench are covered with the second insulating film interposed,
wherein the trap storage pattern is formed to be separated from the first and second source/drain regions, and
wherein the trench is the recessed region.

15. The method of forming a silicon-oxide-nitride-oxide-silicon memory cell as set forth in claim 14, which comprises forming the first and second source/drain regions sequentially.

16. The method of forming a silicon-oxide-nitride-oxide-silicon memory cell as set forth in claim 14, which comprises
planarizing the trap storage film until the first insulating film positioned on the top surface of the substrate is exposed, and
forming the trap storage pattern to be as high as the exposed first insulating film.
